(19) United States
(12) Patent Application Publication
(10) Pub. No.: US 2008/0251934 A1
(43) Pub. Date: Oct. 16, 2008

(54) Semiconductor Device Structures and Methods of Fabricating Semiconductor Device Structures for Use in SRAM Devices

(76) Inventors: Jack Allan Mandelman, Flat Rock, NC (US); Haining Yang, Wappingers Falls, NY (US)

Correspondence Address: WOOD, HERRON & EVANS, L.L.P. (IBM), 2700 CAREW TOWER, 441 VINE STREET, CINCINNATI, OH, 45202, US

(21) Appl. No.: 11/734,931

(22) Filed: Apr. 13, 2007

(51) Int. Cl. H01L 29/267; H01L 21/3205

(52) U.S. Cl. 257/777; 438/586; 257/E29.081; 257/E21.294

(57) ABSTRACT

Semiconductor device structures and methods of fabricating such semiconductor device structures for use in static random access memory (SRAM) devices. The semiconductor device structure comprises a dielectric region disposed between first and second semiconductor regions and a gate conductor structure extending between the first and second semiconductor regions. The gate conductor structure has a first sidewall overlying the first semiconductor region. The device structure further comprises an electrically connective bridge extending across the first semiconductor region. The electrically connective bridge has a portion that electrically connects a impurity-doped region in the first semiconductor region with the first sidewall of the gate conductor structure.

### FIELD OF THE INVENTION

The invention relates to semiconductor device structures and methods of fabricating such semiconductor device structures and, in particular, to semiconductor device structures and fabrication methods for use in memory cells found in SRAM devices.

### BACKGROUND OF THE INVENTION

Static random access memory (SRAM) devices execute both read and write operations on its memory cells to manipulate and access stored binary data or binary operating states. The memory cells of conventional SRAM devices are typically fabricated in an integrated circuit chip with a matrix or array arrangement. Address decoding in the integrated circuit chip permits access to each individual SRAM memory cell for read and write functions.

SRAM memory cells rely on active feedback from cross-coupled inverters in the form of a bistable latch to store or “latch” a bit of information. Typically, a high binary operating state (i.e., a high logic level) is approximately equal to the power supply voltage, Vdd, and a low binary operating state (i.e., a low logic level) is approximately equal to a reference voltage, usually ground potential. The binary operating state of the bistable latch is switched during a write operation by application of a voltage. SRAM memory cells are designed to hold a stored binary operating state until the held value is overwritten by a new value, if the memory cell is reprogrammed, or until power is lost.

Standard SRAM memory cells may have various different constructions. One representative construction for a conventional SRAM memory cell, which is frequently referred to as a 6T cell, consists of six transistors. Four of the transistors are cross-coupled to implement the bistable latch and two of the transistors provide access to read and write the binary operating state of the cell. Two of the cross-coupled transistors are n-channel pull-down transistors and two of the cross-coupled transistors are p-channel pull-up transistors are arranged in a cross-coupled inverter configuration to define the bistable latch. Two additional n-channel pass-gate transistors operating as the cell-access transistors.

One continuing objective of SRAM device designers is to more densely pack SRAM memory cells into a smaller integrated circuit. However, at and below the 45 nm node, contacts to diffusions and gates (i.e., CA contacts) within the SRAM cell become difficult to properly form with conventional photolithography. Conventionally, optical proximity correction (OPC) is applied when forming CA contacts to improve their resolution on the substrate. Specifically, OPC systematically increases the size and modifies the shape of features patterned in a resist mask used to form the CA contacts. The changes imparted by OPC to the resist mask compensate for inadequacies in the photolithographic process by compensating image errors arising from diffraction or process effects. When the mask image is printed with OPC applied, the resulting shape of each CA contact feature forms a distinct contact area of acceptable size and shape. However, there may be insufficient area in high-density SRAM layouts available to properly apply OPC for enlarging patterned features to ensure that all of the CA contacts for each SRAM memory cell reliably open on a consistent basis. One or more closed CA contacts results in a defective SRAM memory cell.

The inability to reliably compensate with OPC for inadequacies in the photolithographic process may be especially true for the particular CA contacts used by the conductor lines of metal-1 (M1) level interconnect wiring to cross couple the two inverters in each SRAM memory cell. More specifically, these CA contacts electrically contact the internal nodes of the M1 level wiring that provide connection between the drains of pull-down and pull-up field effect transistors of the first inverter and the gate electrode of the second inverter and also connect the drains of pull-down and pull-up field effect transistors of the second inverter and the gate electrode of the first inverter.

SRAM memory cell layouts may also be limited by the minimum layout requirements incurred by the M1 level interconnect wiring for cross-coupling the inverters. SRAM memory cells can be scaled by decreasing the sizes of the transistors and the sizes of the conductor lines that provide electrical paths for accessing each SRAM memory cell. Such feature size reduction places ever-greater demands on the photolithography techniques used to form the features. Adjacent conductor lines of the M1 level interconnect wiring are separated by an insulator-filled space. Because of limiting factors such as optics and wavelength of the radiation, conventional photolithography techniques have a minimum line and space (i.e., pitch) below which features cannot be reliably formed. Thus, the minimum pitch available for conventional lithographic techniques may represent an obstacle to continued feature size reduction in SRAM memory cell layouts.

At the current point in the development cycle for integrated circuits, the minimum allowable line and space sizes for the M1 level interconnect wiring is 70 nm and 70 nm, respectively (i.e., a pitch of 140 nm). To lay out a SRAM memory cell with the required size at or below the 45 nm technology node, fitting the M1 level interconnect wiring into the SRAM memory cell requires that the “minimum area rule” be violated. Moreover, the conventional photolithography tools can only resolve line widths of about 90 nm, which may hinder further reductions in the pitch of the M1 level interconnect wiring.

High-density SRAM memory cells fabricated at, and below, the 45 nm node may suffer from the “foreshortening” of the printed gate conductor pattern in the SRAM memory cell. At smaller geometries, the printed space between narrow collinear features is generally recognized to be significantly larger than the space at the design level. This foreshortening effect is especially critical for the gate electrodes in the SRAM memory cell. Specifically, the tip-to-tip space between adjacent minimum width and collinear gate electrode lines cannot be printed smaller than about 120 nm using conventional photolithography. Accordingly, the SRAM cell layout is modified to provide sufficient room for reliably separating the collinear conductor lines defining the gate electrodes. The relatively large tip-to-tip space for adjacent gate electrodes at the design level forces an increased space between adjacent CA contact regions in the SRAM layout. This results in a significant density penalty.

What is needed, therefore, are improved semiconductor device structures and methods used to interconnect the transistors in a conventional SRAM memory cell while simultaneously either reducing the number of CA contacts or completely eliminating CA contacts.

### SUMMARY OF THE INVENTION

In one embodiment, a semiconductor device structure comprises a first semiconductor region having an impurity-doped region, a second semiconductor region juxtaposed with the first semiconductor region, and a dielectric region between the first and second semiconductor regions. A gate conductor structure extends between the first and second semiconductor regions. The gate conductor structure has a sidewall overlying the first semiconductor region. An electrically connective bridge on the first semiconductor region electrically connects the impurity-doped region in the first semiconductor region with the sidewall of the gate conductor structure.

In one embodiment, a method is provided for fabricating a semiconductor device structure in a substrate comprising juxtaposed first and second semiconductor regions separated by an intervening dielectric region. The method comprises forming an impurity-doped region in the first semiconductor region, forming a conductor line extending across the dielectric region and between the first and second semiconductor regions, and removing a section of the conductor line to define a sidewall overlying the first semiconductor region. The method further comprises forming an electrically connective bridge on the first semiconductor region that electrically connects the impurity-doped region in the first semiconductor region with the sidewall of the conductor line.

Embodiments of the invention provide structures and methods for eliminating those CA contacts conventionally used by metal-1 (M1) level wiring to cross couple the two inverters in each SRAM memory cell, thus enabling a denser cell layout, while at the same time reliably opening the other remaining CA contacts.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIGS. 1-6 are diagrammatic cross-sectional views of a portion of a substrate at successive fabrication stages of a processing method in accordance with an embodiment of the invention.

FIG. 5A is a diagrammatic cross-sectional view taken generally along line 5A-5A in FIG. 5.

FIG. 5B is a diagrammatic cross-sectional view taken generally along line 5B-5B in FIG. 5.

FIGS. 7-12 are diagrammatic cross-sectional views of a portion of a substrate at successive fabrication stages of a processing method in accordance with an embodiment of the invention.

FIGS. 13-18 are diagrammatic cross-sectional views of a portion of a substrate at successive fabrication stages of a processing method in accordance with an embodiment of the invention.

FIG. 17A is a diagrammatic cross-sectional view taken generally along line 17A-17A in FIG. 17.

FIG. 17B is a diagrammatic cross-sectional view taken generally along line 17B-17B in FIG. 17.

FIG. 17C is a diagrammatic cross-sectional view taken generally along line 17C-17C in FIG. 17.

### DETAILED DESCRIPTION

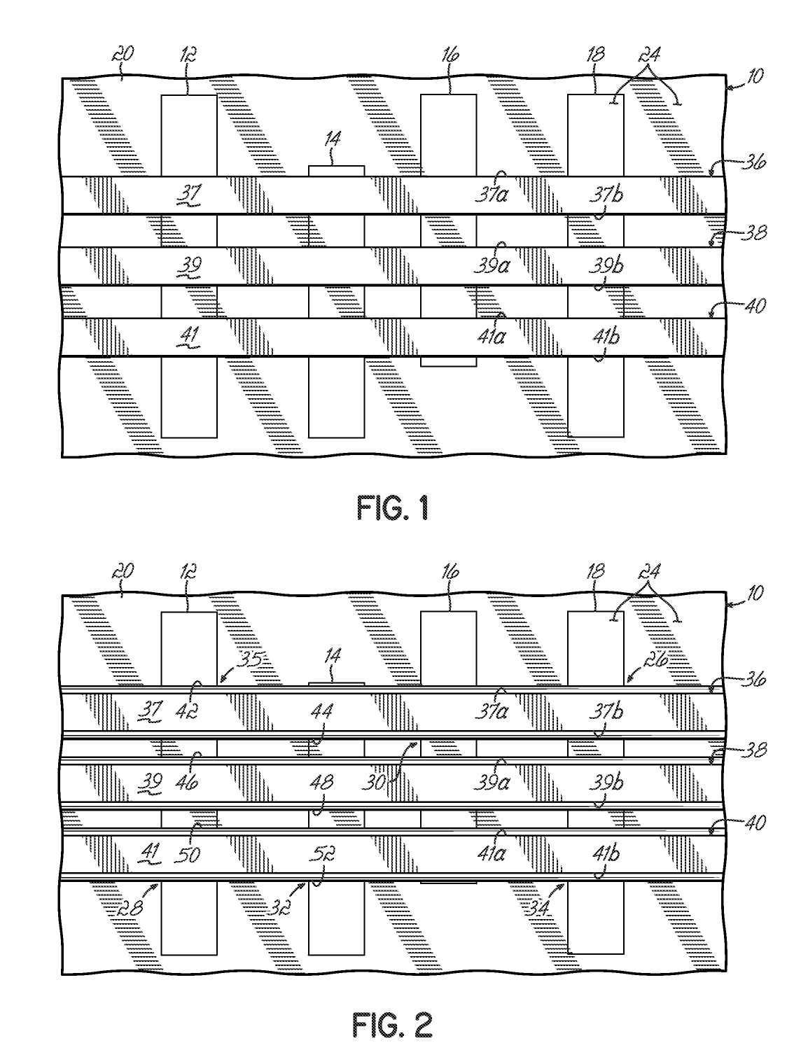

With reference to FIG. 1, a substrate 10 for use in fabricating an integrated circuit includes a plurality of active semiconductor regions, including the representative active semiconductor regions 12, 14, 16, 18, that are used for device fabrication. The substrate 10 further includes a bulk region 11 underlying and electrically coupled with regions 12, 14, 16, 18. The substrate 10 and active semiconductor regions 12, 14, 16, 18 are formed from a silicon-containing semiconductor material that primarily contains silicon. For example, the substrate 10 and active semiconductor regions 12, 14, 16, 18 may be formed from monocrystalline silicon.

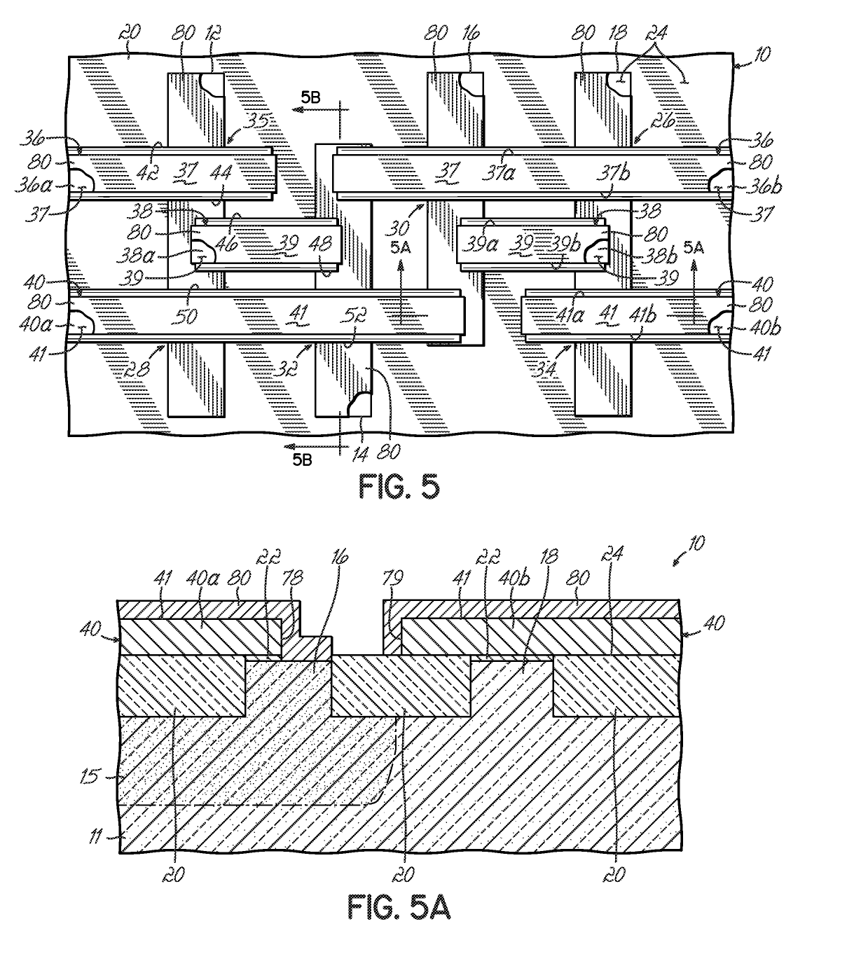

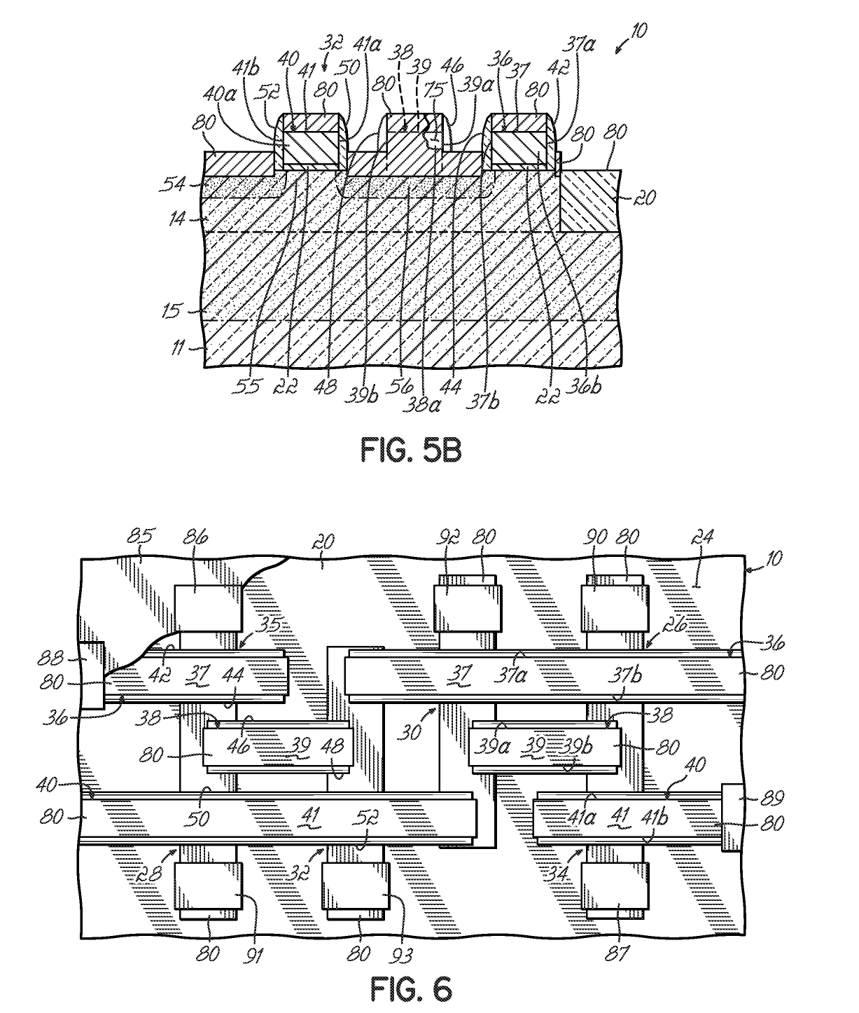

The substrate 10 includes shallow trench isolations, generally indicated by reference numeral 20, that electrically isolate adjacent active semiconductor regions 12, 14, 16, 18 from each other. Active semiconductor regions 12, 14, 16, 18, and shallow trench isolation regions 20 are fabricated by standard processes understood by a person having ordinary skill in the art. A well region 15 (FIGS. 5A, 5B) of an opposite conductivity type to the active semiconductor regions 12, 18 is formed in the semiconductor material of the active semiconductor regions 14, 16 and the bulk region 11 underlying regions 14, 16. The well region 15 is doped with a concentration of an appropriate impurity to have an opposite conductivity type in comparison with the active semiconductor regions 12, 14, 16, 18.

A gate dielectric layer 22 (FIG. 5B) is formed on a top surface 24 shared by the active semiconductor regions 12, 14, 16, 18 and shallow trench isolation regions 20. The gate dielectric layer 22 may comprise a thin film of silicon oxide (SiO₂), silicon oxynitride (SiOₓN_{y}), or any other insulating material with suitable physical and dielectric properties for use in field effect transistors. In particular, the gate dielectric layer 22 may be grown on the active semiconductor regions 12, 14, 16, 18 by a thermal oxidation process that exposes regions 12, 14, 16, 18 to an oxygen laden, heated ambient in, for example, an oxidation furnace or a rapid thermal anneal chamber. The thickness of the gate dielectric layer 22 is contingent upon the required performance of the underlying semiconductor devices.

Conductor lines 36, 38, 40 are formed with a given line-space pattern on the top surface 24. Each of the conductor lines 36, 38, 40 is physically separated and electrically isolated from the active semiconductor regions 12, 14, 16, 18 by an intervening portion of the gate dielectric layer 22. Conductor line 36 has opposite sidewalls 37a,b that intersect the top surface 24 common to the shared by the active semiconductor regions 12, 14, 16, 18 and shallow trench isolation regions 20 and that are connected by a top surface 37 of line 36. Conductor line 38 includes opposite sidewalls 39a,b that intersect the top surface 24 and a top surface 39 connects the sidewalls 39a,b. Similarly, conductor line 40 has opposite sidewalls 41a,b that intersect top surface 24 and a top surface 41 that connects sidewalls 41a,b.

Conductor lines 36, 38, 40 are formed from a silicon-containing semiconductor material that primarily contains silicon, such as doped polycrystalline silicon (i.e., doped polysilicon). The conductor lines 36, 38, 40 may be defined by a conventional photolithography and etching process that deposits a conductive material in a layer on the gate dielectric layer 22, forms a resist layer with a suitable line-space pattern that serves as an etch mask for the underlying layer of conductive material, and then etches using an anisotropic etching process that removes the layer of the conductive material and the gate dielectric layer 22 in exposed areas of the patterned resist layer. Adjacent pairs of the conductor lines 36, 38, 40, which have a parallel, collinear arrangement, are separate by intervening spaces that eventually are filled by dielectric material.

Although a minimum line width-minimum space pattern is illustrated in the exemplary embodiment, other combinations of line width for conductor lines 36, 38, 40 and spaces, or sub-minimum pitch may be used as well. For example, it is contemplated that sub-minimum line width for conductor lines 36, 38, 40 or space may be formed by sidewall image transfer methods, instead of pure photolithography, or by “Split and Shift Exposure” (SASE, as presented by Intel at SPIE Microlithography, 2006), the disclosure of which is incorporated by reference herein in its entirety.

With reference to FIG. 2 in which like reference numerals refer to like features in FIG. 1 and at a subsequent fabrication stage, sidewall spacers 42, 44 are formed on the sidewalls 37a,b of conductor line 36, sidewall spacers 46, 48 are formed on the sidewalls 39a,b of conductor line 38, and sidewall spacers 50, 52 are formed on the sidewalls 41a,b of conductor line 40. The spacers 42, 44, 46, 48, 50, 52 are formed using a conventional technique, such as depositing a blanket layer of an insulator or dielectric, such as silicon nitride (Si₃N₄), silicon dioxide (SiO₂), or a combination of these materials deposited by CVD, followed by etching the blanket layer using a conventional anisotropic etching technique, such as reactive ion etching (RIE) or plasma etching, that remove portions of the blanket dielectric layer from substantially horizontal surfaces at a faster rate than from substantially vertical surfaces.

Source-drain extension, halo and high-concentration implants for the cell transistors are executed at various stages during the formation of the spacers 42, 44, 46, 48, 50, 52. Source/drain extensions and halos (not shown) may be implanted into semiconductor regions 12, 14, 16, 18 adjacent to the conductor lines 36, 38, 40 either before spacer formation or with at an early formation stage at which the spacers 42, 44, 46, 48, 50, 52 are relatively thin. Source and drain regions for cell transistors 26, 28, 30, 32, 34, 35, such as the source and drain regions 54, 56 (FIGS. 5A, 5B) for transistor 32, are also formed in semiconductor regions 12, 14, 16, 18 by, for example, an ion implantation process with the spacers 42, 44, 46, 48, 50, 52 at, or near, their final thickness. In each instance, the implantations into the active semiconductor regions 12, 14, 16, 18 are self-aligned to the positions of the conductor lines 36, 38, 40 and spacers 42, 44, 46, 48, 50, 52 due to the masking effect of the conductor lines 36, 38, 40 and spacers 42, 44, 46, 48, 50, 52.

At the conclusion of this fabrication stage, an n-channel pull-down transistor 26 of a SRAM memory cell is defined in active semiconductor region 18 and includes a gate conductor structure defined by the overlying conductor line 36. Another n-channel pull-down transistor 28 of the SRAM memory cell is defined in active semiconductor region 12 and includes a gate conductor structure defined by the overlying conductor line 40. A p-channel pull-up transistor 30 is defined in active semiconductor region 16 and includes a gate conductor structure defined by the overlying conductor line 36. Another p-channel pull-up transistor 32 of the SRAM memory cell is defined in active semiconductor region 14 with a gate conductor structure defined by the overlying conductor line 40. An n-channel pass-gate transistor 34 of the SRAM memory cell is defined in active semiconductor region 18 with a gate conductor structure defined by the overlying conductor line 40. Another n-channel pass-gate transistor 35 of the SRAM memory cell is defined in active semiconductor region 12 with a gate conductor structure defined by the overlying conductor line 36. The SRAM memory cell comprises a 6T cell, although the invention is not so limited.

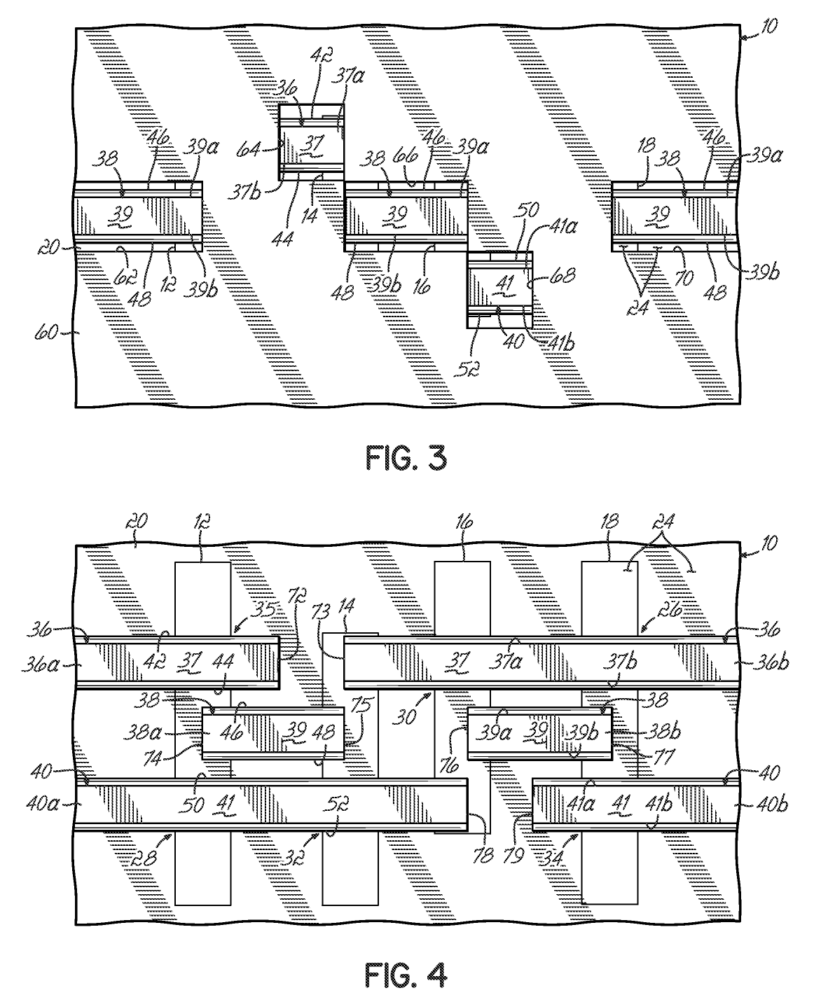

With reference to FIG. 3 in which like reference numerals refer to like features in FIG. 2 and at a subsequent fabrication stage, a photoresist layer 60 is applied to the substrate 10 and openings 62, 64, 66, 68, 70 characteristic of a trim or cut mask are printed in the photoresist layer 60 using a conventional photolithography process. This process may involve exposing the photoresist layer 60 to a pattern of radiation to generate a latent pattern and developing the latent pattern to define the openings 62, 64, 66, 68, 70.

With reference to FIG. 4 in which like reference numerals refer to like features in FIG. 3 and at a subsequent fabrication stage, portions of the conductor lines 36, 38, 40 and underlying gate dielectric layer 22 exposed by openings 62, 64, 66, 68, 70 are then removed using an anisotropic dry etching process, such as RIE. The chemistry of the etching process, which may be conducted in a single etching step or multiple steps, removes the materials of the conductor lines 36, 38, 40 and the gate dielectric layer 22 selective to the materials of the active semiconductor regions 12, 14, 16, 18 and shallow trench isolation regions 20. The etching process also removes the exposed portions of the spacers 42, 44, 46, 48, 50, 52. Alternatively, the etching process may spare the spacers 42, 44, 46, 48, 50, 52. After the etching process concludes, the remnants of the photoresist layer 60 (FIG. 3) are stripped by, for example, plasma ashing or a chemical stripper.

The etching process segments the conductor lines 36, 38, 40. One segment 36a of the conductor line 36 has an exposed substantially vertical surface on a sidewall 72 overlying one of the shallow trench isolation regions 20. Another segment 36b of the conductor line 36, which is collinear with segment 36a, has an exposed substantially vertical surface on a sidewall 73 overlying the active semiconductor region 14. One segment 38a of the conductor line 38 has exposed substantially vertical surfaces on sidewalls 74, 75 overlying the active semiconductor regions 12, 14, respectively. Another segment 38b of the conductor line 38, which is collinear with segment 38a, has exposed substantially vertical surfaces on sidewalls 76, 77 overlying the active semiconductor regions 16, 18, respectively. One segment 40a of the conductor line 40 has an exposed substantially vertical surface on a sidewall 78 overlying the active semiconductor region 16. Another segment 40b of the conductor line 40, which is collinear with segment 40a, has an exposed substantially vertical surface on a sidewall 79 overlying one of the shallow trench isolation regions 20.

Only the relative narrow transverse edges or ends defining sidewalls 72-79 of the conductor lines 36, 38, 40 are cut and exposed by the etching process at the locations of the openings 62, 64, 66, 68, 70 in the photoresist layer 60 (FIG. 3). The segmentation of conductor lines 36, 38, 40 by the etching process occurs in the sequence of the fabrication process for the SRAM memory cell after the spacers 42, 44, 46, 48, 50, 52 are formed. Thus, only the sidewalls 72-79 and respective top surfaces 37, 39, 41 of the conductor lines 36, 38, 40 are not protected against silicide formation in a subsequent silicidation process step by the spacers 42, 44, 46, 48, 50, 52.

With reference to FIGS. 5, 5A, 5B in which like reference numerals refer to like features in FIG. 4 and at a subsequent fabrication stage, a silicide layer 80 is formed on the top surface 24 of the active semiconductor regions 12, 14, 16, 18 not covered by the conductor lines 36, 38, 40 and spacers 42, 44, 46, 48, 50, 52. The silicide layer 80 is also formed on the respective top surface 37, 39, 41 of each of the conductor lines 36, 38, 40. The silicide layer 80 also forms on the sidewalls 72-79 of the conductor lines 36, 38, 40 that are exposed by etching. However, sidewalls 37a,b of conductor line 36, sidewalls 39a,b of conductor line 38, and sidewalls 41a,b of conductor line 40 are protected against silicide formation by the spacers 42, 44, 46, 48, 50, 52.

Silicidation processes are familiar to a person having ordinary skill in the art. In one silicidation process, the silicide layer 80 may be formed by depositing a layer of suitable metal, such as nickel, cobalt, tungsten, titanium, etc., across the substrate 10 and then subjecting the substrate 10 to an anneal by, for example, a rapid thermal annealing process. During the high temperature anneal, the metal reacts with the silicon-containing semiconductor material (e.g., silicon) of the active semiconductor regions 12, 14, 16, 18 and the silicon-containing semiconductor material (e.g., doped polysilicon) of the conductor lines 36, 38, 40 to form the silicide layer 80. The silicidation process may be conducted in an inert gas atmosphere or in a nitrogen-rich gas atmosphere, and at a temperature of about 350° C. to about 800° C. depending on the type of silicide being considered. After the anneal concludes, unreacted metal remains on the shallow trench isolation regions 20 and spacers 42, 44, 46, 48, 50, 52 (i.e., where the deposited metal is not in contact with a silicon-containing material). Unreacted metal is in contact with insulators comprising shallow trench isolation regions 20 and spacers 42, 44, 46, 48, 50, 52. The unreacted metal is then selectively removed from the shallow trench isolation regions 20 and spacers 42, 44, 46, 48, 50, 52 with an isotropic wet chemical etch process. The process self aligns the silicide to the exposed silicon-containing regions because of the selective reaction between the metal and silicon-containing semiconductor material and is called “self-aligned silicide” or salicide.

The internal nodes of the M1 level interconnect wiring are coupled without forming any dedicated CA contacts. Specifically, the drains of the pull-down and pull-up transistors 28, 32 of a first inverter are electrically coupled with each other by the segment 38a of the conductor line 38 extending between active semiconductor regions 12, 14. The gate conductor structure of a second inverter is defined by the segment 36b of the conductor line 36 extending across active semiconductor regions 16, 18. The sidewall 73 of the gate conductor structure defined by segment 36b is electrically coupled with the sidewall 75 of the segment 38a of the conductor line 38 by electrically connective bridges defined by respective portions of the silicide layer 80 on sidewalls 73, 75 and by the portion of the silicide layer 80 on the active semiconductor region 14 between the sidewalls 73, 75.

The drains of the pull-down and pull-up transistors 26, 30 of the second inverter are electrically coupled with each other by the segment 38b of the conductor line 38 extending between active semiconductor regions 16, 18. The gate conductor structure of the first inverter is defined by the segment 40a of the conductor line 40 extending across active semiconductor regions 12, 14. The sidewall 78 of the gate conductor structure defined by segment 40a is electrically coupled with the sidewall 76 of the segment 38b of the conductor line 38 by electrically connective bridges defined by portions of the silicide layer 80 on sidewalls 76, 78 and by the portion of the silicide layer 80 on the active semiconductor region 16 between the sidewalls 76, 78.

After the conductor lines 36, 38, 40 are segmented and before the silicide layer 80 is formed, additional high-concentration implants may optionally be performed into the newly exposed portions of the active semiconductor regions 12, 14, 16, 18 revealed by the etching process. The additional doping from the high-concentration implants facilitates the formation of low-resistance connections between the active semiconductor regions 12, 14, 16, 18 and the conductor lines 36, 38, 40 via the subsequently formed electrically connective bridges.

In comparison with conventional SRAM memory cells, the interior contacts for forming the local cross-coupled wiring are eliminated. Connections between the common gate of one inverter and the drain of the other inverter in the cell are established with electrically connective bridges and relatively short line segments of conductor lines 36, 38, 40.

As best shown in FIG. 5A, a portion of the silicide layer 80 on segment 40a of conductor line 40 extends across the top surface 41 and along the sidewall 78 to merge with a portion of the silicide layer 80 on active semiconductor region 16. The sidewall 78 is in direct physical contact with this portion of the silicide layer 80 and without any intervening structures, such as a spacer. Similarly, a portion of the silicide layer 80 on segment 40b of conductor line 40 extends across the top surface 41 and along the sidewall 79 to terminate on one of the shallow trench isolation regions 20. These portions of the silicide layer 80 participate in forming one of the electrically connective bridges for the inverters.

As best shown in FIG. 5B, the sidewalls 41a,b, of conductor line 40 are covered by the spacers 50, 52 and, thus, electrically isolated from the silicide layer 80. A portion of the silicide layer 80 on segment 38a of conductor line 38 extends across the top surface 39 and along the sidewall 75 to merge with a portion of the silicide layer 80 on active semiconductor region 14. These portions of the silicide layer 80, which are electrically coupled with drain region 56 for transistor 32, participate in forming one of the electrically connective bridges. The sidewall 75 is in direct physical contact with this portion of the silicide layer 80 without any intervening structures, such as a spacer.

Transistor 32 includes the source and drain regions 54, 56 that are disposed on opposite sides of a channel region 55 and a gate conductor structure defined by a portion of the line segment 40a that overlies the channel region 55. Transistors 26, 28, 30, 34, 35 have similar constructions to the construction of transistor 32. In particular, transistor 28 has a drain region (not shown) in active semiconductor region 12 that is electrically connected by line segment 38a of conductor line 38 and portions of silicide layer 80 on sidewalls 74, 75 with drain 56 of transistor 32 and, therefore, with sidewall 73 of segment 38a of the conductor line 38.

Transistors 26 and 30 of the other inverter have similar electrical connections as transistors 28, 32. In particular, portions of the silicide layer 80 on sidewalls 76, 78, as well as a portion of the silicide layer 80 on active semiconductor region 16, define electrically connective bridges for coupling the gate conductor structure defined by line segment 40a with the drains of transistors 26, 30. Line segment 40a defines the gate conductor structure for transistors 28, 32.

With reference to FIG. 6 in which like reference numerals refer to like features in FIG. 5 and at a subsequent fabrication stage, a dielectric layer 85 is applied and CA contacts 86-93 are formed in the dielectric layer 85 by conventional techniques to provide connection to various structures in the SRAM memory cell. CA contacts 86, 87 are positioned in the SRAM memory cell to couple diffusions in active semiconductor regions 12, 18 with bit lines (not shown). CA contacts 88, 89 are positioned in the SRAM memory cell to couple the gate conductor structure of the first and second inverters with word lines (not shown). CA contacts 90, 91 are positioned in the SRAM memory cell to couple diffusions in active semiconductor regions 12, 18 with a ground potential (GND) line. CA contacts 92, 93 are positioned in the SRAM memory cell to couple in active semiconductor regions 14, 16 with a power supply potential (Vdd) line.

Standard processing follows, which includes metallization for the M1 level interconnect wiring, and interlayer dielectric layers, conductive vias, and metallization for upper level (M2-level, M3-level, etc.) interconnect wiring. However, interior M1 level interconnect wiring is eliminated as described above, which removes the need for M1 level lithographic scaling.

In an alternative embodiment and as described below in conjunction with FIGS. 6-12, local cross-coupled interconnects may be formed by a combination of electrically connective bridges and short, simplified line segments of the M1 level interconnect wiring. Although interior CA contacts are utilized to connect the M1 level interconnect wiring for cross-coupling the first and second inverters, the use of electrically connective bridges for a portion of the wiring facilitates smaller interior CA contacts.

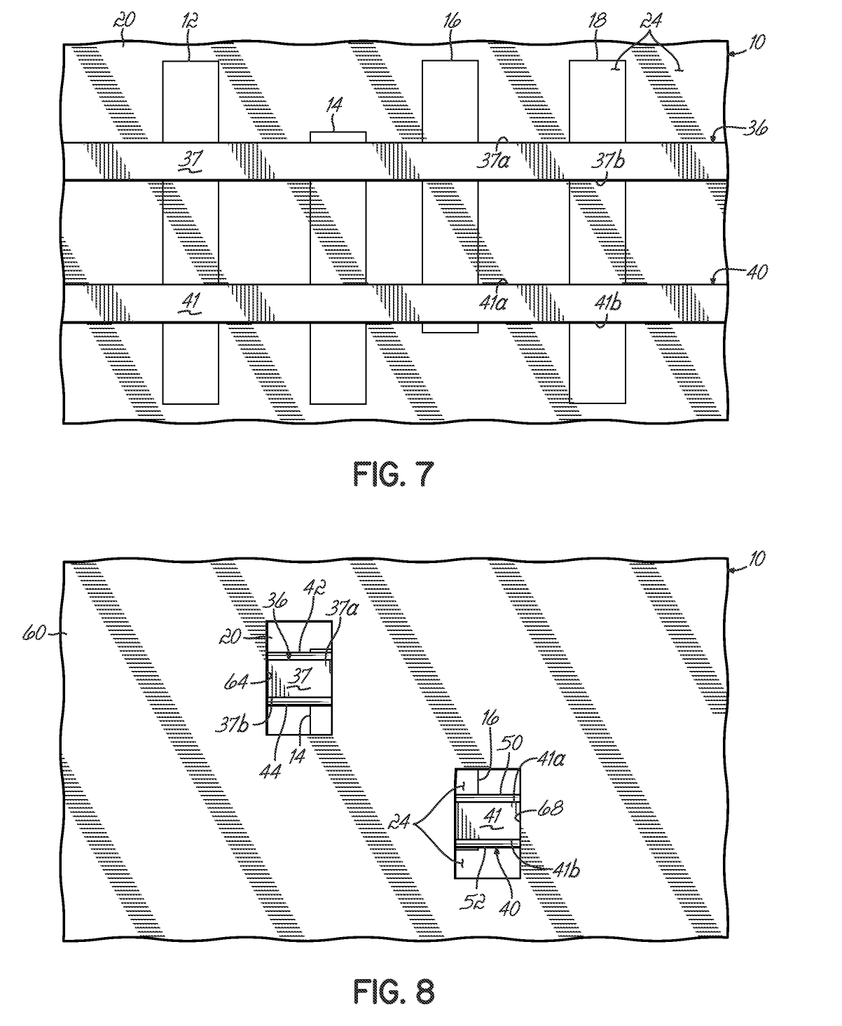

With reference to FIG. 7 in which like reference numerals refer to like features in FIGS. 1 and 2 and in accordance with the alternative embodiment, conductor lines 36, 40 are formed on the substrate 10 as described above with regard to FIG. 1. However, conductor line 38 is omitted. In this embodiment, the pitch for the conductor lines 36, 40 is relaxed because conductor line 38 is not subsequently used to form portions of the interior cross-coupled interconnects. The spacers 42, 44 for conductor line 36, the spacers 50, 52 for conductor line 40, and the transistors 26, 28, 30, 32, 34, 35 are fabricated as described above with regard to FIG. 2.

With reference to FIG. 8 in which like reference numerals refer to like features in FIGS. 3 and 7 and at a subsequent fabrication stage to FIG. 7, the photoresist layer 60 is applied to the substrate 10 as described above with regard to FIG. 2. However, the photoresist layer 60 only includes openings 64, 68. Openings 62, 66, 70 are eliminated because of the absence of a conductor line between conductor lines 36, 40.

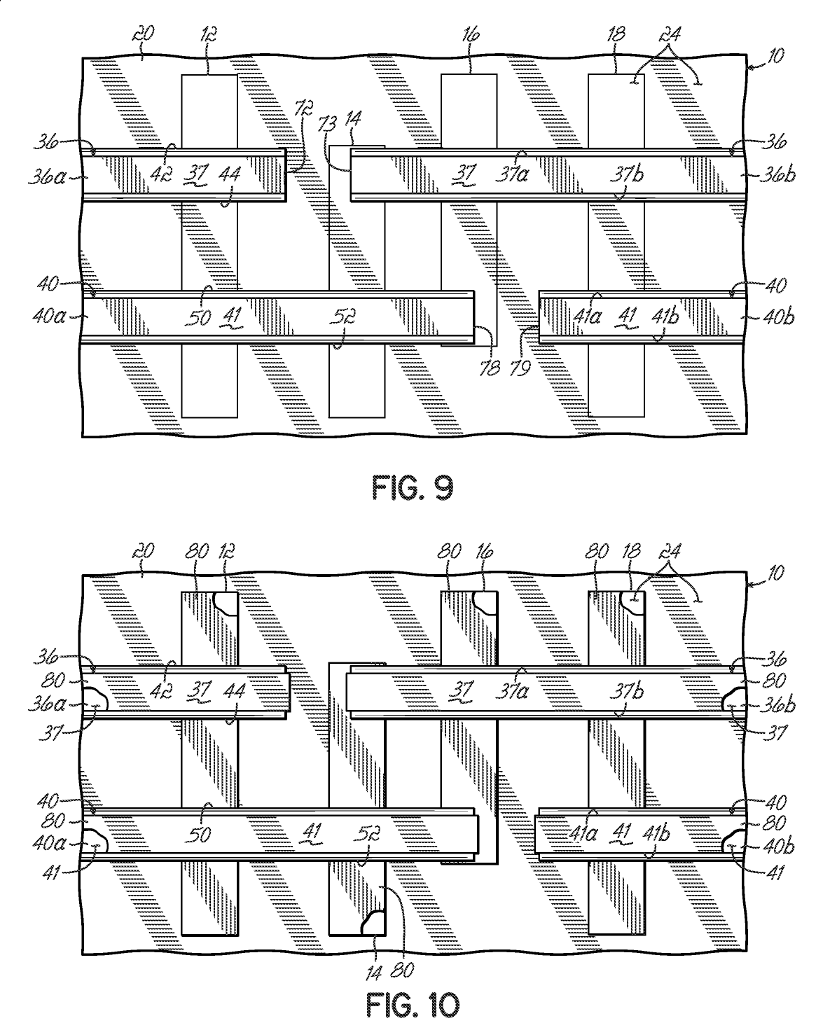

With reference to FIG. 9 in which like reference numerals refer to like features in FIGS. 4 and 8 and at a subsequent fabrication stage to FIG. 8, the conductor lines 36, 40 are segmented as described above with regard to FIG. 4. Additional high-concentration implants may optionally be performed into the newly exposed portions of the active semiconductor regions 14, 16, as described above with regard to FIG. 5.

With reference to FIG. 10 in which like reference numerals refer to like features in FIGS. 5 and 9 and at a subsequent fabrication stage to FIG. 9, silicide layer 80 is formed on the top surface 24 of the active semiconductor regions 12, 14, 16, 18 not covered by the conductor lines 36, 40 and spacers 42, 44, 50, 52. The silicide layer 80 is also formed on the top surface 37 of conductor line 36 and on the top surface 41 of conductor line 40. The silicide layer 80 also forms on the sidewalls 72, 73, 78, 79 of the conductor lines 36, 40 that are exposed by etching. The silicide layer 80 is formed as described above with regard to FIG. 5. Sidewalls 73 and 78 are each in direct physical contact with a corresponding portion of the silicide layer 80 without any intervening structures, such as a spacer.

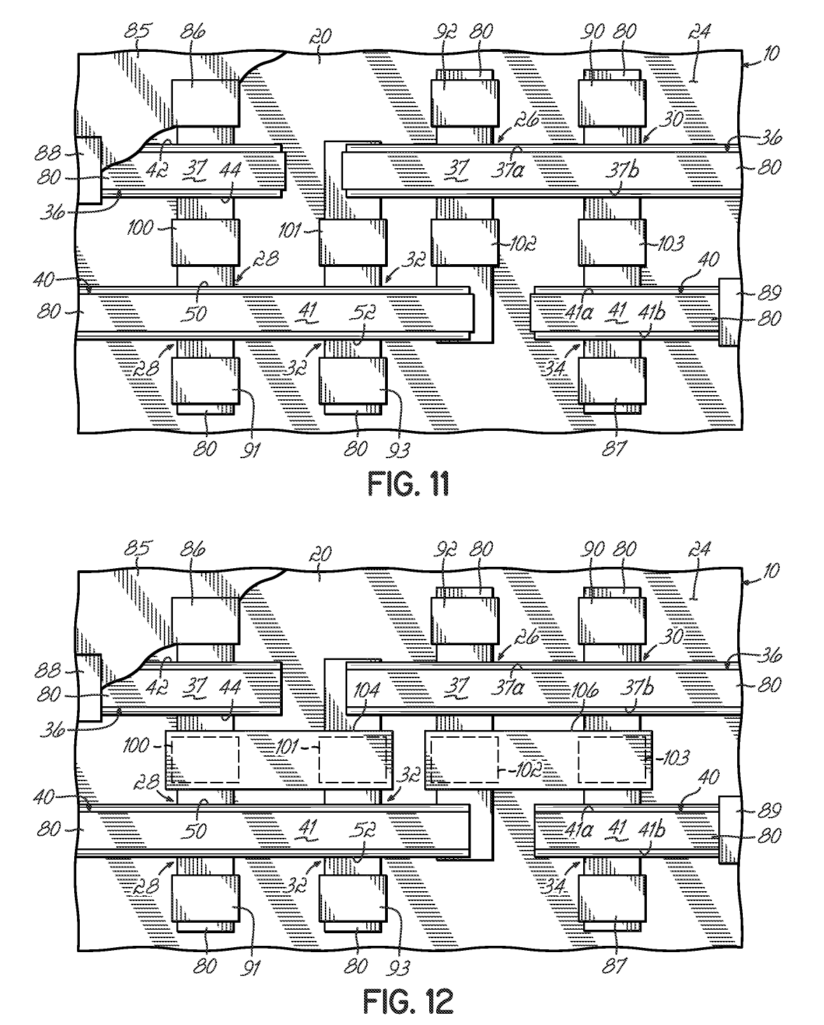

With reference to FIG. 11 in which like reference numerals refer to like features in FIGS. 6 and 10 and at a subsequent fabrication stage to FIG. 10, the CA contacts 86-93 are formed in the dielectric layer 85 by conventional techniques to provide connection to various points in the SRAM memory cell, as described above with regard to FIG. 6. Additional CA contacts 100-103 are formed when CA contacts 86-93 are formed. CA contacts 100-101 supply the interior contacts for creating the local cross-coupled wiring between the diffusions in the active semiconductor regions 12, 14, 16, 18 that comprise drains of the inverters and gate electrode structures of the inverters. However, the size requirements for the additional interior CA contacts 101, 102 are relaxed because of the use of the electrically connective bridges, which enables more reliable printing of all CA contacts 86-93, 100-103.

With reference to FIG. 12 in which like reference numerals refer to like features in FIG. 11 and at a subsequent fabrication stage, metallization lines 104, 106 of the M1 level interconnect wiring are defined in a conventional manner to form the interior cross-coupled interconnections for the internal nodes of the M1 level interconnect wiring. Metallization line 104 defines an electrically connective bridge between contacts 100, 101. Metallization line 106 defines a conductive bridge between contacts 102, 103.

Specifically, the drains of the pull-down and pull-up transistors 28, 32 of a first inverter are electrically coupled with each other by metallization line 104 and contacts 100, 101. The gate conductor structure of a second inverter is defined by the segment 36b of the conductor line 36 extending across active semiconductor regions 16, 18. The sidewall 73 of the gate conductor structure defined by segment 36b is electrically coupled with metallization line 104 by electrically connective bridges defined by respective portions of the silicide layer 80 on sidewall 73 and by the portion of the silicide layer 80 on the active semiconductor region 14 between the sidewall 73 and metallization line 104.

The drains of the pull-down and pull-up transistors 26, 30 of the second inverter are electrically coupled with each other by metallization line 106 and contacts 102, 103. The sidewall 78 of the gate conductor structure, which is defined by the segment 40a of the conductor line 40 extending across active semiconductor regions 12, 14, of the first inverter is electrically coupled with the sidewall 76 of the segment 38b of the conductor line 38 by electrically connective bridges defined by portions of the silicide layer 80 on sidewalls 76, 78 and by the portion of the silicide layer 80 on the active semiconductor region 16 between the sidewalls 76, 78.

Consequently, the gate of each inverter and the drains of the other inverter are electrically coupled by a combination of the segmented conductor lines 36, 40 and electrically connective bridges contributed by the silicide layer 80. The connection between each of the conductor lines 36, 40 and the respective one of the adjacent active semiconductor regions 14, 16 is now made by an electrically connective bridge. The M1-level interconnect wiring has a simplified shape promoted by the incorporation and use of the segmented conductor lines 36, 40, which eliminates some of the CA contacts in comparison with conventional M1-level interconnect wiring designs. Because the CA contact density is lower, this alleviates problems relating to conventionally printing the CA contacts using OPC. In particular, the resulting reduction in size of the interior CA contact requires a smaller OPC mask shape, which in turn permits all CA contacts to receive proper OPC. Furthermore, the lowered CA contact density alleviates problems relating to constraints on cell scalability in M1-level interconnect wiring schemes. In particular, the shape of the interconnecting M1-level interconnect wiring is simplified, because the electrically connective bridge now forms a portion of the interconnect. This makes the layout of the M1-level interconnect wiring in the cell less challenging for device designs.

After the conductor lines 36, 40 are segmented and before the silicide layer 80 is formed, additional high-concentration implants may optionally be performed into the newly exposed portions of the active semiconductor regions 12, 14, 16, 18 revealed by the etching process. Standard processing follows, which includes metallization for the M1 level interconnect wiring, and interlayer dielectric layers, conductive vias, and metallization for upper level (M2, M3, etc.) interconnect wiring.

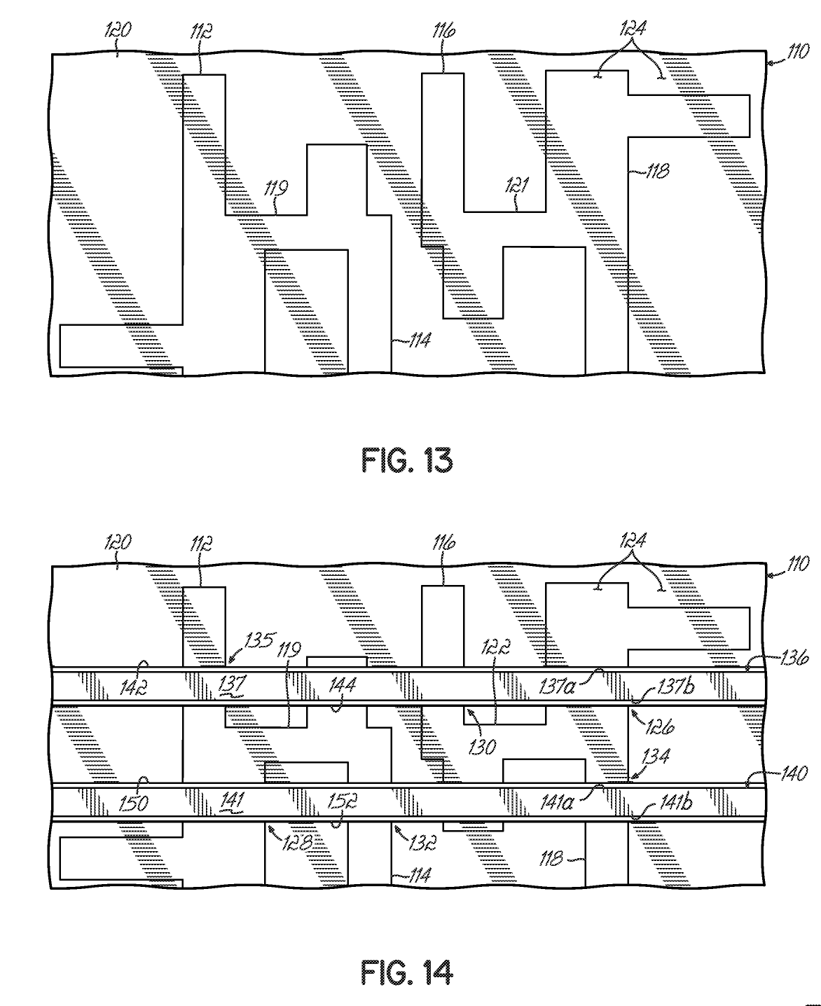

In another alternative embodiment and as described below in conjunction with FIGS. 13-18, electrically connective bridges in combination with semiconductor bridges between the active semiconductor regions define the interior cross-coupled interconnects. This third embodiment is specifically applicable to situations in which substrate 10 is an SOI substrate because butting of N⁺ and P⁺ source-drain diffusions, which forms the bridge between adjacent active semiconductor regions, is permitted only for SOI technology. The interior CA contacts and the interior portion of the M1-level interconnect wiring are eliminated, which promotes reliable printing of all remaining CA contacts and eliminates M1-level layout imposed scaling constraints on the SRAM memory cell.

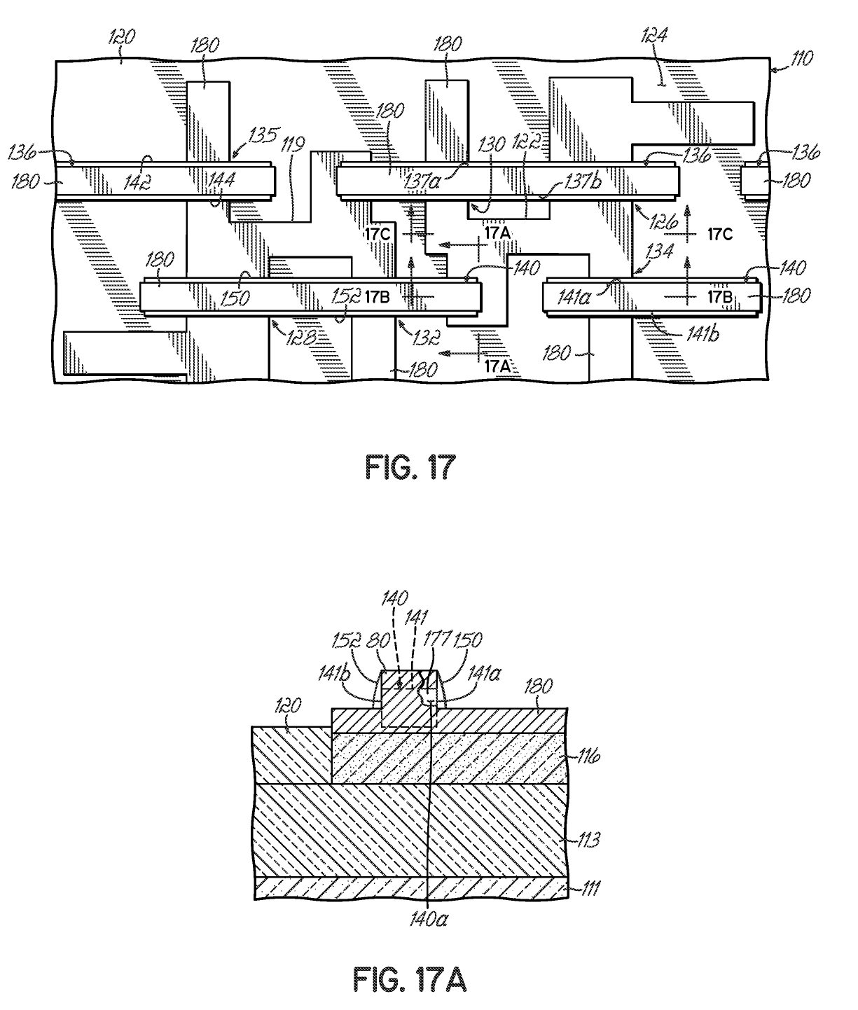

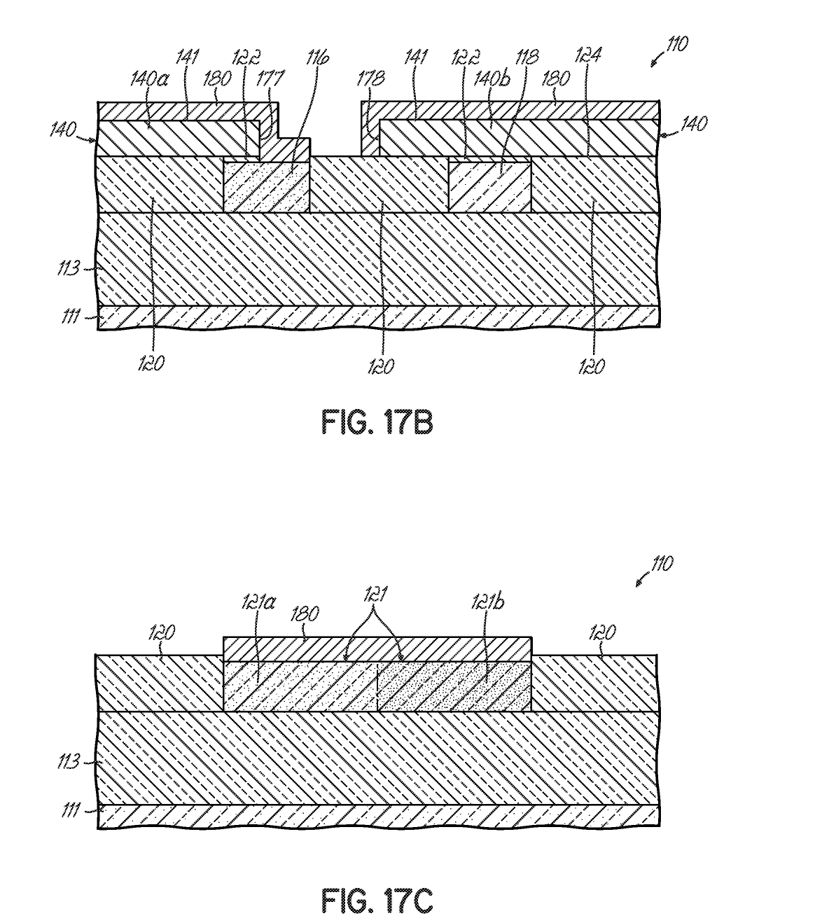

With reference to FIG. 13 and in accordance with the alternative embodiment, a semiconductor-on-insulator substrate 110 for an integrated circuit includes a plurality of active semiconductor regions, including the representative active semiconductor regions 112, 114, 116, 118, that are used for device fabrication. Shallow trench isolation regions 120 electrically isolate adjacent regions 112, 114, 116, 118 from each other. An electrically connective bridge 119 of semiconductor material connects active semiconductor regions 112 and 114. An electrically connective bridge 121 of semiconductor material connects active semiconductor regions 116, 118. The active semiconductor regions 112, 114, 116, 118 and semiconductor bridges 119, 121 are fashioned from a semiconductor layer separated from a handle wafer 111 (FIGS. 17A-C) by the dielectric layer 113. The active semiconductor regions 112, 114, 116, 118 and semiconductor bridges 119, 121 contain silicon and, in one embodiment, are monocrystalline silicon.

The active semiconductor regions 112, 114, 116, 118 and semiconductor bridges 119, 121, and the shallow trench isolation regions 120 are formed by standard processes understood by a person having ordinary skill in the art on an insulating or dielectric layer 113 (FIGS. 17A-C). The active semiconductor regions 112, 114, 116, 118 and semiconductor bridges 119, 121 may be formed using either standard lithography or a combination of standard lithography and sidewall image transfer (SIT) methods, such as the SIT method disclosed in application Ser. No. 11/379,634, which is hereby incorporated by reference herein in its entirety. The use of sidewall image transfer methods improves the scalability of the pattern for the active semiconductor regions 112, 114, 116, 118 and semiconductor bridges 119, 121 to 45 nm and below.

A gate dielectric layer 122 (FIG. 17A-C) is formed on a top surface 124 of the active semiconductor regions 112, 114, 116, 118 and shallow trench isolation regions 120, as described above with regard to FIG. 1.

With reference to FIG. 14 in which like reference numerals refer to like features in FIG. 13 and at a subsequent fabrication stage, conductor lines 136, 140 are formed with a given line-space pattern on the top surface 124. The conductor lines 136, 140 are formed by methods and have characteristics as described with regard to conductor lines 36, 38, 40 (FIG. 1). The conductor lines 136, 140 are separated and electrically isolated from the active semiconductor regions 112, 114, 116, 118 by a space consisting of a residual portion of the gate dielectric layer 122. Conductor line 136 has opposite sidewalls 137a,b that intersect the top surface 124 and a top surface 137 that connects sidewalls 137a,b. Conductor line 140 includes opposite sidewalls 141a,b that intersect the top surface 124 and a top surface 141 that connects sidewalls 141a,b. The conductor lines 136, 140 have a relaxed pitch for their line-space pattern in comparison with pattern printing in conventional SRAM memory cell designs.

Sidewall spacers 142, 144 are formed on the sidewalls 137a,b of conductor line 136 and sidewall spacers 150, 152 are formed on the sidewalls 141a,b of conductor line 140. The sidewall spacers 142, 144, 150, 152 are formed by methods and have characteristics as described with regard to sidewall spacers 42, 44, 46, 48, 50, 52 (FIG. 2).

Transistors 126, 128, 130, 132, 134, 135 characteristic of a SRAM memory cell are formed as described above with regard to FIG. 2. An n-channel pull-down transistor 126 is defined in active semiconductor region 118 with a gate conductor structure defined by the overlying conductor line 136. Another n-channel pull-down transistor 128 is defined in active semiconductor region 112 with a gate conductor structure defined by the overlying conductor line 140. A p-channel pull-up transistor 130 is defined in active semiconductor region 116 with a gate conductor structure defined by the overlying conductor line 136. Another p-channel pull-up transistor 132 is defined in active semiconductor region 114 with a gate conductor structure defined by the overlying conductor line 140. An n-channel pass-gate transistor 134 is defined in active semiconductor region 118 with a gate conductor structure defined by the overlying conductor line 140. Another n-channel pass-gate transistor 135 is defined in active semiconductor region 112 with a gate conductor structure defined by the overlying conductor line 136.

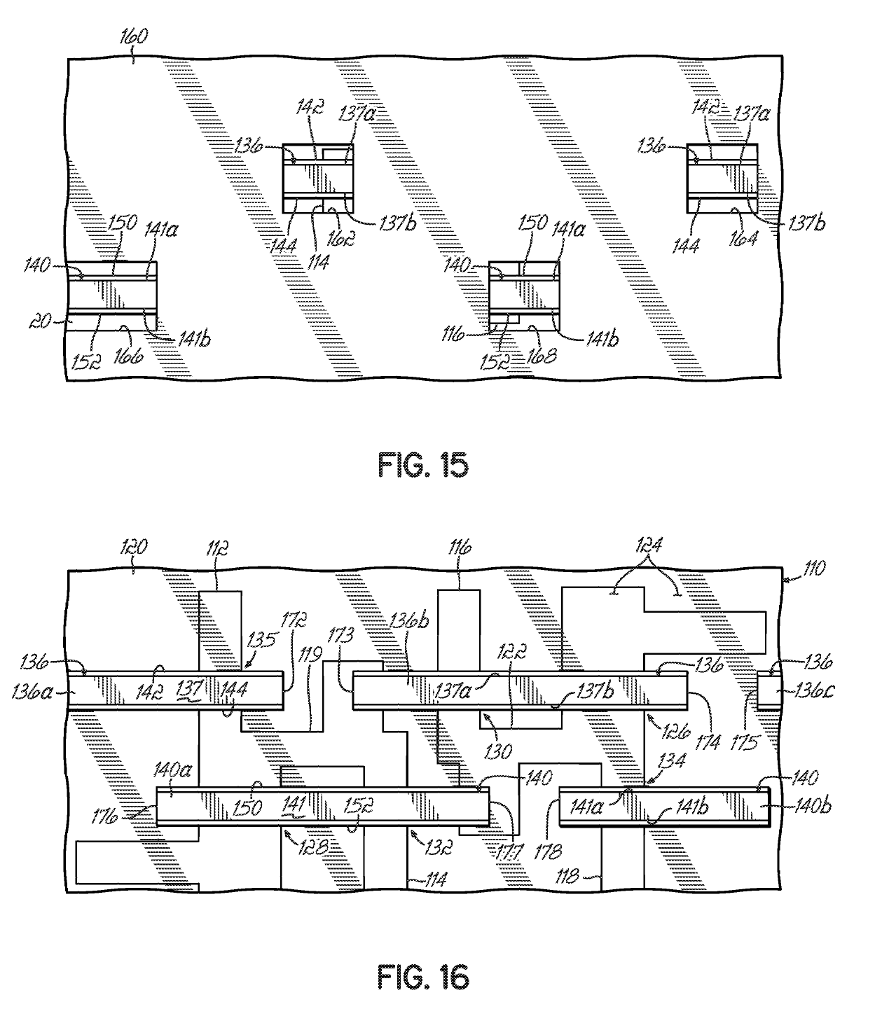

With reference to FIG. 15 in which like reference numerals refer to like features in FIG. 14 and at a subsequent fabrication stage, a photoresist layer 160 is applied to the substrate 10 and openings 162, 164, 166, 168 characteristic of a trim or cut mask are printed in the photoresist layer 160 using a conventional photolithography process, as described above with regard to photoresist layer 60 (FIG. 3).

With reference to FIG. 16 in which like reference numerals refer to like features in FIG. 15 and at a subsequent fabrication stage, portions of the conductor lines 136, 140 and underlying gate dielectric layer 122 exposed by openings 162, 164, 166, 168 are then removed using an anisotropic dry etching process, such as RIE, as described above with regard to FIG. 3. The etching process segments conductor line 136 into a first segment 136a having an exposed substantially vertical surface on a sidewall 172 overlying one of the shallow trench isolation regions 120, a second segment 136b having an exposed substantially vertical surface on a sidewall 173 overlying the active semiconductor region 114, and a third segment 136c. The second segment 136b and third segment 136c have respective exposed substantially vertical surfaces on confronting sidewalls 174, 175 overlying another of the shallow trench isolation regions 120. The etching process segments conductor line 140 into a first segment 140a having an exposed substantially vertical surface on a sidewall 176 overlying one of the shallow trench isolation regions 120 and an exposed substantially vertical surface on a sidewall 177 overlying the active semiconductor region 116, and a second segment 140b having an exposed substantially vertical surface on a sidewall 178 overlying another of the shallow trench isolation regions 120.

Only the relatively narrow transverse edges or ends defining sidewalls 172-178 of the conductor lines 136, 140 are cut and exposed by the etching process at the locations of the openings 162, 164, 166, 168 in the photoresist layer 160 (FIG. 15). The conductor lines 136, 140 are segmented in the sequence of the fabrication process for the SRAM memory cell after the spacers 142, 144, 150, 152 are formed. Consequently, only the sidewalls 172-178 and respective top surfaces 137, 141 of the conductor lines 136, 140 are not protected against silicide formation in a subsequent silicidation process step by the spacers 142, 144, 150, 152.

With reference to FIGS. 17, 17A-C in which like reference numerals refer to like features in FIG. 16 and at a subsequent fabrication stage, a silicide layer 180 is formed on the top surface 124 of the active semiconductor regions 112, 118 not covered by the conductor lines 136, 140 and spacers 142, 144, 150, 152. The silicide layer 180 also forms on the respective top surface 137, 141 of each of the conductor lines 136, 140. The silicide layer 180 also forms on the sidewalls 172-178 of the conductor lines 136, 140 that are exposed by etching. However, the sidewalls 137a,b of conductor line 136 and the sidewalls 141a,b of conductor line 140 are protected against silicide formation by the presence of the spacers 142, 144, 150, 152. The process for forming the silicide layer 180 is described above with regard to silicide layer 80 (FIG. 5). Sidewalls 173 and 177 are in direct physical contact with a corresponding portion of the silicide layer 180 without any intervening structures, such as a spacer.

The internal nodes of the M1 level interconnect wiring are coupled by the semiconductor bridges 119, 121. Specifically, the drain of the pull-down transistor 128 and the drain of the pull-up transistor 132 of a first inverter are electrically coupled with each other by semiconductor bridge 119. The sidewall 173 of the gate conductor structure, which is defined by the segment 136b of the conductor line 136 extending across active semiconductor regions 116, 118, of a second inverter is electrically coupled with semiconductor bridge 119 by an electrically connective bridge defined by a portion of the silicide layer 180 on sidewalls 173 and by the portion of the silicide layer 180 on the active semiconductor region 114 between the sidewall 173 and semiconductor bridge 119. Sidewall 75 is in a direct physical contacting relationship with this portion of the silicide layer 180 without any intervening structures, such as a spacer.

The semiconductor bridge 121 electrically couples the drains of the pull-down and pull-up transistors 126, 130 of the second inverter with each other. The sidewall 177 of the gate conductor structure, which is defined by the segment 140a of the conductor line 140 extending across active semiconductor regions 112, 114, of the first inverter is electrically coupled with the semiconductor bridge 121 by an electrically connective bridge defined by a portion of the silicide layer 180 on sidewall 177 and by the portion of the silicide layer 180 on the active semiconductor region 116 between the sidewall 177 and the semiconductor bridge 121.

After the conductor lines 136, 140 are segmented and before the silicide layer 180 is formed, additional high-concentration implants may optionally be performed into the newly exposed portions of the active semiconductor regions 112, 114, 116, 118 revealed by the etching process. The additional doping from the high-concentration implants facilitates the formation of low-resistance connections between the active semiconductor regions 112, 114, 116, 118 and the conductor lines 136, 140 via the subsequently formed electrically connective bridges.

As best shown in FIG. 17A, a portion of the silicide layer 180 on the sidewall 177 of segment 140a of conductor line 140 merge with a portion of the silicide layer 180 on active semiconductor region 116 to participate in forming one of the electrically connective bridges. As described above, the silicide layer 80 does not form on the adjacent shallow trench isolation region 120.

As best shown in FIG. 17B, a portion of the silicide layer 180 on segment 140a of conductor line 140 extends across the top surface 141 and along the sidewall 177 to merge with a portion of the silicide layer 180 on active semiconductor region 116. These portions of the silicide layer 180 participate in forming one of the electrically connective bridges. Similarly, a portion of the silicide layer 180 on segment 140b of conductor line 140 extends across the top surface 141 and along the sidewall 178 to terminate on one of the shallow trench isolation regions 120.

As best shown in FIG. 17C, a portion of the silicide layer 180 forms a strap that assists in electrically coupling abutted diffusion regions 121a, 121b of different electrical conductivity type in the semiconductor bridge 121.

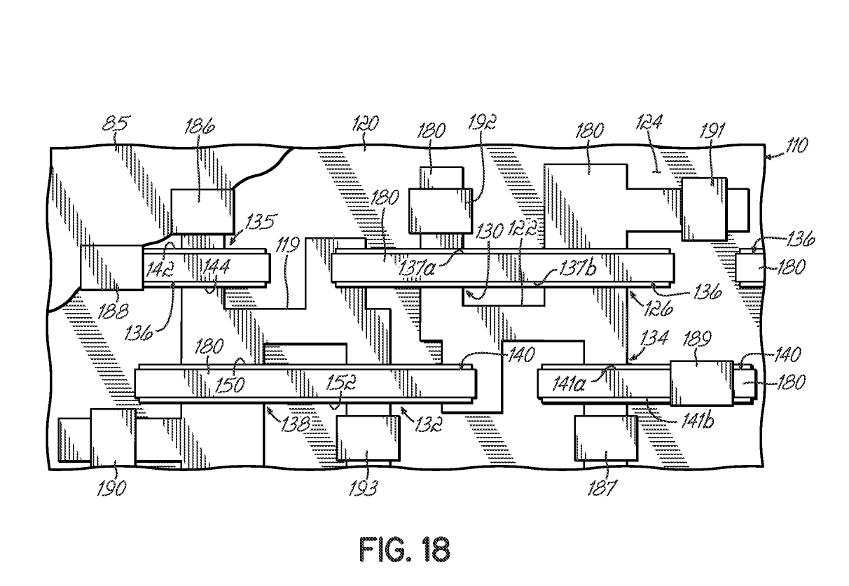

With reference to FIG. 18 in which like reference numerals refer to like features in FIG. 17, 17A-C and at a subsequent fabrication stage, CA contacts 186-193 are formed in the dielectric layer 85 by conventional techniques to provide connection to various points in the SRAM memory cell. Specifically, CA contacts 186, 187 are positioned in the SRAM memory cell to couple diffusions in active semiconductor regions 12, 18 with bit lines (not shown). CA contacts 188, 189 are positioned in the SRAM memory cell to couple the gate conductor structure of the first and second inverters with word lines (not shown). CA contacts 190, 191 are positioned in the SRAM memory cell to couple diffusions in active semiconductor regions 12, 18 with a ground potential (GND) line. CA contacts 192, 193 are positioned in the SRAM memory cell to couple in active semiconductor regions 14, 16 with a power supply potential (Vdd) line.

Standard processing follows, which includes metallization for the M1 level interconnect wiring, and interlayer dielectric layers, conductive vias, and metallization for upper level (M2-level, M3-level, etc.) interconnect wiring. The interior cross-coupled local interconnects are formed by the series combination of the semiconductor bridges 119, 121 and electrically connective bridges defined by silicide layer 180, as described above. As such, no M1-level interconnect wiring is used to form the interior cross-coupled interconnects.

Cell scaling, which was limited by the minimum layout requirements incurred by the M1-level interconnect wiring, is no longer an issue with the SRAM memory cell of FIG. 18. Furthermore, because no interior CA contacts are used, proper OPC and reliable printing of the remaining CA contacts 186-193 is achieved.

In an analogous conventional SRAM memory cell, the abutted diffusion regions 121a, 121b in the semiconductor bridge 121 are coupled by an elongated CA contacts (the CABAR contact) that bridges between the conductor line 140 and the semiconductor bridge 121. A similar elongated CABAR contact is required to couple the semiconductor bridge 119 with the conductor line 136. These elongated CABAR contacts and the surrounding CA contacts 186-193 are extremely difficult to print in the cell layout shown, because insufficient room is available for proper OPC. The use of the silicide layer 180 and the electrically connective bridges in this embodiment of the invention eliminates the need for the CABAR contacts.

References herein to terms such as “vertical”, “horizontal”, etc. are made by way of example, and not by way of limitation, to establish a frame of reference. The term “horizontal” as used herein is defined as a plane parallel to a conventional plane of a semiconductor wafer or substrate, regardless of its actual three-dimensional spatial orientation. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the embodiments of the invention. The term “on” used in the context of two layers means at least some contact between the layers. The term “over” means two layers that are in close proximity, but possibly with one or more additional intervening layers such that contact is possible but not required. As used herein, neither “on” nor “over” implies any directionality.

The fabrication of the semiconductor structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the invention. It is also understood that features of the invention are not necessarily shown to scale in the drawings.

While the invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A semiconductor device structure comprising:
a first semiconductor region having an impurity-doped region;
a second semiconductor region juxtaposed with the first semiconductor region;
a first dielectric region between the first and second semiconductor regions;
a first gate conductor structure extending across the first dielectric region from the first semiconductor region to the second semiconductor region, the first gate conductor structure having a first sidewall overlying the first semiconductor region; and
a first electrically connective bridge on the first semiconductor region, the first electrically connective bridge electrically connecting the first impurity-doped region in the first semiconductor region with the first sidewall of the first gate conductor structure.

2. The device structure of claim 1 wherein the first gate conductor structure includes second and third sidewalls connected by the first sidewall, the second and third sidewalls extending from the first sidewall across the first semiconductor region, the first dielectric region, and the second semiconductor region.

3. The device structure of claim 2 wherein the first sidewall and a portion of the electrically connective bridge are in direct physical contact, and further comprising:
a first dielectric spacer on the second sidewall of the first gate conductor structure; and
a second dielectric spacer on the third sidewall of the first gate conductor structure.

4. The device structure of claim 1 further comprising:
a third semiconductor region juxtaposed with the first semiconductor region so that the first semiconductor region is between the second and third semiconductor regions, the third semiconductor region having an impurity-doped region; and
a second dielectric region between the first and third semiconductor regions.

5. The device structure of claim 4 further comprising:
a conductor line extending across the second dielectric region from the first semiconductor region to the third semiconductor region, the conductor line having a first sidewall overlying the second semiconductor region and a second sidewall overlying the third semiconductor region, and the conductor line electrically connecting the first and second impurity-doped regions.

6. The device structure of claim 5 wherein the first electrically connective bridge has another portion that electrically connects the impurity-doped region in the first semiconductor region with the first sidewall of the conductor line.

7. The device structure of claim 4 further comprising:
a semiconductor bridge spanning the first dielectric region to connect the second and third active semiconductor regions, the semiconductor bridge electrically connecting the first and second impurity-doped regions.

8. The device structure of claim 4 further comprising:
a first contact electrically coupled with the impurity-doped region in the first semiconductor region;
a second contact electrically coupled with the impurity-doped region in the second semiconductor region; and
a metallization line defining an electrically connective bridge between the first and second contacts.

9. The device structure of claim 1 wherein the impurity-doped region comprises a drain of a first transistor, further comprising:
a second transistor with a source region defined in the second semiconductor region, a drain region defined in the second semiconductor region, and a channel region defined in the second semiconductor region between the source and drain regions, a portion of the first gate conductor structure overlying the channel region.

10. The device structure of claim 1 wherein the first gate conductor structure comprises a conductor line segmented into a first line segment carrying the first sidewall and a second line segment with a second sidewall confronting the first sidewall, the first and second line segments being collinear.

11. The device structure of claim 10 further comprising:
a second dielectric region proximate to the first semiconductor region, the second sidewall of the second line segment overlying the second dielectric region.

12. The device structure of claim 1 wherein the first electrically connective bridge comprises a metal silicide layer having a first portion on the first semiconductor region and a second portion on the first sidewall of the first gate conductor structure, the first and second portions electrically connected with each other.

13. The device structure of claim 1 wherein the second semiconductor region includes a second impurity-doped region, and further comprising:
a second gate conductor structure extending between the first and second semiconductor regions, the second gate conductor structure having a second sidewall overlying the second semiconductor region; and
a second electrically connective bridge extending across the second semiconductor region, the second electrically connective bridge electrically connecting the second impurity-doped region in the second semiconductor region with the second sidewall of the second gate conductor structure.

14. A method for fabricating a semiconductor device structure in a substrate comprising juxtaposed first and second semiconductor regions and a first dielectric region between the first and second semiconductor regions, the method comprising:
forming a first impurity-doped region in the first semiconductor region;
forming a first conductor line extending across the first dielectric region and between the first and second semiconductor regions;
removing a section of the first conductor line to define a first sidewall overlying the first semiconductor region; and
forming a first electrically connective bridge on the first semiconductor region that electrically connects the first impurity-doped region in the first semiconductor region with the first sidewall of the first conductor line.

15. The method of claim 14 wherein removing the section of the first conductor line further comprises:
applying a trim mask with an opening that exposes the section of the conductor line; and
etching the exposed section of the conductor line.

16. The method of claim 15 wherein the first conductor line has second and third sidewalls connected by the first sidewall, the second and third sidewalls extending from the first sidewall across the first semiconductor region, the first dielectric region, and the second semiconductor region, and further comprising:
applying sidewall spacers to the second and third sidewalls before the exposed section of the first conductor line is etched.

17. The method of claim 14 further comprising:
forming a second conductor line extending across the first dielectric region and between the first and second semiconductor regions wherein the first and second conductor lines are substantially parallel and separated by a space; and
removing a section of the second conductor line to define a second sidewall overlying the first semiconductor region and a third sidewall overlying the second semiconductor region.

18. The method of claim 17 wherein forming the first electrically connective bridge further comprises:
forming a metal silicide layer having a first portion on the first semiconductor region, a second portion on the first sidewall of the first conductor line, and a third portion on the second sidewall of the second conductor line, wherein the first, second, and third portions are of the metal silicide layer are electrically connected with each other.

19. The method of claim 14 wherein the first conductor line has second and third sidewalls connected by the first sidewall, the second and third sidewalls extending from the first sidewall across the first semiconductor region, the first dielectric region, and the second semiconductor region, and further comprising:
applying sidewall spacers to the second and third sidewalls before the section of the first conductor line is removed.

20. The method of claim 14 wherein forming the first electrically connective bridge further comprises:
forming a metal silicide layer having a first portion on the first semiconductor region and a second portion on the first sidewall of the gate conductor structure, wherein the first and second portions of the metal silicide layer are electrically connected with each other.

21. The method of claim 20 further comprising:
forming a second conductor line substantially parallel to the first conductor line and separated by a space from the first conductor line; and
removing a section of the second conductor line to define a second sidewall overlying the first semiconductor region.

22. The method of claim 21 wherein the metal silicide has a third portion on the second sidewall that is electrically connected with the first and second portions.

23. The method of claim 14 wherein the substrate further comprises a third semiconductor region juxtaposed with the first semiconductor region and a second dielectric region between the first and third semiconductor regions, and further comprising:
forming a second impurity-doped region in the second semiconductor region;
forming a second conductor line extending across the second dielectric region and between the first and third semiconductor regions; and
removing a section of the second conductor line to define a second sidewall overlying the first semiconductor region and a third sidewall overlying the third semiconductor region.

24. The method of claim 23 further comprising:
forming a second electrically connective bridge extending across the first semiconductor region that electrically connects the first impurity-doped region in the first semiconductor region with the sidewall of the second conductor line.

25. The method of claim 25 further comprising:
forming a third electrically connective bridge extending across the third semiconductor region that electrically connects the second impurity-doped region in the second semiconductor region with the sidewall of the second conductor line.
